(19) United States
(12) Patent Application Publication
(10) Pub. No.: US 2026/0305183 A1
(43) Pub. Date: Oct. 1, 2026

(54) VAN DER WAALS MOIRÉ HOMOBILAYER FOR GATE-TUNABLE FRACTIONAL QUANTUM ANOMALOUS HALL STATE

(71) Applicant: University of Washington, Seattle, WA (US)

(72) Inventors: Eric Anderson, Seattle, WA (US); Jiaqi Cai, Seattle, WA (US); Xiaodong Xu, Seattle, WA (US)

(73) Assignee: University of Washington, Seattle, WA (US)

(21) Appl. No.: 19/476,058

(22) PCT Filed: Apr. 15, 2024
(86) PCT No.: PCT/US2024/024656

§ 371 Date: Oct. 16, 2025

Related U.S. Application Data
(60) Provisional application No. 63/496,473, filed on Apr. 17, 2023.

(51) Int. Cl. H10N 52/00; H10N 52/85

(52) U.S. Cl. CPC H10N 52/101; H10N 52/85

(57) ABSTRACT

Presented is an opto-electronic device that utilizes a semiconducting molybdenum ditelluride homobilayer in a rhombohedral stacked moiré superlattice as the active component. The semiconducting molybdenum ditelluride monolayers are arranged into a homobilayer moiré superlattice where the layers are rotated by between 2.5 to 4 degrees. The device is constructed from the molybdenum ditelluride homobilayer moiré superlattice. The homobilayers are sandwiched between few-layer flakes of hexagonal boron nitride and graphite. Fractional quantum anomalous Hall states result when the device is cooled below 4.5 Kelvin and gate voltages are applied. The described devices can be used for developing topological qubits towards error-immune quantum computing.

### CROSS-REFERENCE TO RELATED APPLICATION

This application claims the benefit of and priority to U.S. Provisional Patent Application No. 63/496,473, filed Apr. 17, 2023, the contents of which are hereby incorporated by reference in its entirety.

### STATEMENT OF GOVERNMENT LICENSE RIGHTS

This invention was made with Government support under Grant Nos. DE-SC0018171 and DE-SC0019443, awarded by the U.S. Department of Energy; Grant Nos. FA9550-19-1-0390 and FA9550-21-1-0177, awarded by the Air Force Office of Scientific Research (AFOSR/JA) and Grant No. DGE-2140004, awarded by the National Science Foundation (NSF). The Government has certain rights in the invention.

### BACKGROUND

If a magnetic field in the \hat{z} direction is applied to a conductor with an electric current flowing in the x direction, a voltage difference in the y direction will result. This behavior, called the Hall effect, was discovered by Edwin Hall in 1879. More recently, a quantized version of the Hall effect has been discovered experimentally and explained theoretically. The quantum Hall effect (QHE) manifests as a precisely quantized value for the Hall resistance

$${R}_{x y} = \frac{{V}_{y}}{{I}_{x}} of \frac{h}{{e}^{2} v} ,$$

where υ is an integer. This behavior is explained by the formation of Landau levels in a large applied magnetic field, with v corresponding to the number of filled Landau levels. Each Landau level has a nontrivial topological index, or Chern number, resulting in a single quantum of Hall conductance per filled level. In 1982, the fractional quantum Hall effect (FQHE), with quantized values of the Hall resistance for fractional values of v, was observed. The discoveries of both the integer and fractional quantum Hall effects led to Nobel Prizes in Physics being awarded.

Though the explanation for the QHE is well established, there is still debate regarding the microscopic origin of the various fractional states in the FQHE. Some of these states, which arise from strong correlations between electrons in a partially filled Landau level, were explained by Laughlin. The even denominator states can also be understood via the theory of composite fermions, or bound states of electrons and magnetic flux quanta. In this picture, the FQHE is essentially the QHE of these composite fermions. Remarkably, quasiparticle excitations of fractional quantum Hall states can carry fractions of the electron charge, and exhibit fractional statistics—that is, behaving as neither fermions nor bosons upon exchange. Certain fractional quantum Hall phases are predicted to host excitations with non-Abelian statistics, which can be used as building blocks for a topological quantum computer.

Both the integer and fractional quantum Hall effects rely on a large magnetic field to form Landau levels. An integer quantized Hall resistance without an applied magnetic field, the quantum anomalous Hall effect (QAHE), was achieved in 2013. Observation of the fractional quantum anomalous Hall (FQAH) effect, however, has remained a challenge. Unlike the integer quantum anomalous Hall effect, the fractional quantum anomalous Hall effect relies on strong electron correlations. Thus, it is not only the nontrivial topology but also the flatness of the electronic bands that gives rise to FQAH states. Finding a material with both flat and topologically nontrivial bands which can host FQAH, a fractional Chern insulator (FCI), is therefore a significant challenge.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In one aspect an electrically tunable device, comprising semiconducting molybdenum ditelluride in the form of a first atomic sheet and a second atomic sheet is presented, wherein first atomic sheet is rotated planarly from the second atomic sheet by about 2.5 to about 4 degrees, to form a rhombohedral stacked homobilayer moiré superlattice that hosts ferromagnetic states that spontaneously break time-reversal symmetry.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1A shows a schematic of dual gated device structure.

FIG. 1B shows a rhombohedral-stacked homobilayer hosting two degenerate energy minima at high symmetry MX and XM points, forming a honeycomb moiré superlattice. Complex hopping between next-nearest-neighbor sites realizes topologically nontrivial (Chern) bands.

FIG. 1C is a photoluminescence intensity plot as a function of hole doping and photon energy. Filling factors v corresponding to the formation of correlated insulating states are indicated.

FIG. 2A is a photoluminescence (PL) intensity plot at μₒH=OT as a function of photon energy and filling factor for hole doping. X₀: neutral exciton; X⁺: positively charged trion. Two appreciable trion energy shifts with reduced PL intensity are visible at v=−2/3 and v=−1.

FIG. 2B is a zoomed-in plot of PL near fractional fillings for hole doping. An additional state at v=−3/5 appears as a trion energy shift with reduced PL intensity.

FIG. 2C is a PL intensity plot for electron doping. Multiple states including v=1, 3/4, 4/7, 1/3, and ¼ can be observed. X denotes negatively charged trion.

FIG. 3 shows a Reflective magnetic circular dichroism (RMCD) signal versus v and perpendicular electric field D at zero magnetic field μₒH. The phase space with non-vanishing signal corresponds to the ferromagnetic state.

FIG. 4A is an optical microscope image of the device. Scale bar: 10 μm. RMCD and PL data in the main text are taken in the homogenous region at spots 1 and 2, respectively.

FIG. 4B is RMCD at zero magnetic field vs filling factor and displacement field at spot 1. The electron-doping side is not ferromagnetic.

FIG. 4C is an additional RMCD vs v and D plot at spot 2 which shows an enhancement of the ferromagnetic state at v=−2/3, demonstrating repeatability.

FIG. 4D is an additional RMCD vs v and D plot at spot 3 which shows an enhancement of the ferromagnetic state at v=−2/3, demonstrating repeatability.

FIG. 5 is a plot of RMCD signal versus μₒH swept back and forth at selected fillings.

FIG. 6A shows a RMCD signal intensity plot versus filling factor v and magnetic field swept down (left) and up (right).

FIG. 6B shows the difference of RMCD sweeps in FIG. 2A, ΔRMCD, versus v and μₒH. Clear enhancement of H_{C} at v=−1 and −2/3 is observed.

FIG. 6C is a high-resolution plot of ΔRMCD, versus v and μₒH. In addition to the −2/3 feature, another feature near −3/4 filling is observed.

FIG. 6D shows a H_{C} (left axis) and T_{C} (right axis) versus v. Enhancement of both H_{C} and T_{C} is apparent near −2/3 filling. The value of H_{C} was extracted by change point detection. The shaded area denotes the extracted transition width. The extracted T_{C} has an uncertainty of 0.25K, determined by the temperature step size of the measurement.

FIG. 7A shows doping dependent RMCD hysteresis. RMCD intensity plot versus filling factor v and magnetic field μₒH swept down for spots 1, 2, and 3 as defined in FIG. 4A-4D. For all spots, μₒH_{C} is enhanced near v=−2/3. However, the v=−3/4 state is not visible for spot 2, showing its spatial dependence.

FIG. 7B shows doping dependent RMCD hysteresis. RMCD intensity plot versus filling factor v and magnetic field μₒH swept up for spots 1, 2, and 3 as defined in FIG. 4A-4D. For all spots, μₒH_{C} is enhanced near v=−2/3. However, the v=−3/4 state is not visible for spot 2, showing its spatial dependence.

FIG. 8A shows temperature dependent RMCD at v=−1. The Curie temperature T_{C} is ~14K.

FIG. 8B shows temperature dependent RMCD at v=−2/3. The Curie temperature T_{C} is ~4.5K.

FIG. 9A is a PL intensity plot versus v and photon energy at selected magnetic fields. Dashed lines are guides to the eye.

FIG. 9B is spectrally integrated PL intensity versus μₒH and carrier density n, i.e., an optical Landau fan diagram.

FIG. 9C shows a Wannier diagram corresponding to a C=−1 QAH state at v=−1 (−4.3 n (10⁻¹² cm⁻²) intercept), C=−2/3 fractional QAH (FQAH) state at v=−2/3, and C=−3/5 FQAH state at v=−3/5 (−3 and −2.75 n (10⁻¹² cm⁻²) intercepts), with C equal to the Hall conductance in the units of e²/h. States are marked by (C,v). Overlaid data and error bars are the extracted carrier densities of the three insulating states.

FIG. 9D is the optical Landau fan diagram of FIG. 9B near the fractional fillings, but with a numerical derivative of the integrated PL taken with respect to filling. This additional processing makes the fractional states clearer and reveals an additional dispersing state at v=−4/7.

FIG. 9E is integrated PL intensity versus μₒH and n showing correlated insulating states at electron filling, overlaid with extracted carrier densities of the insulating states. These states do not disperse with magnetic field and are topologically trivial.

FIG. 10 shows the electron doping dependent photoluminescence at selected magnetic fields. No dispersion is observed for any correlated insulating states, implying that the lowest moiré conduction band is topologically trivial.

FIG. 11A is as in FIG. 9A, but with a large applied perpendicular electric field of D/80=−250 mV/nm. The v=−2/3 state is not visible, and the v=−1 state becomes dispersionless and thus topologically trivial.

FIG. 11B is a plot of zero-magnetic field RMCD signal at v=−1 versus electric field, demonstrating an electric field driven magnetic phase transition concurrent with the change in superlattice geometry from honeycomb to triangular (insets).

FIG. 11C is an RMCD signal intensity plot versus v and D at T=3.5K.

FIG. 12 shows the RMCD hysteresis sweeps for selected fillings at T=3.5K. The ferromagnetic states at v=−2/3 and v=−1 retain substantial remnant RMCD signal and sharp spin-flip transitions, signatures of a hard magnet, at this elevated temperature. States at intermediate dopings, however, show behavior consistent with a soft magnet.

FIG. 13 is a plot of RMCD signal versus temperature and D at v=−2/3, highlighting the ferromagnetic phase diagram.

### DETAILED DESCRIPTION

Disclosed herein is a van der Waals heterostructure consisting of a homobilayer moiré superlattice of near-AA stacked 2H molybdenum ditelluride encapsulated between dual gates. The system displays correlated ferromagnetic order when hole doped via the gates. Additionally, band folding due to the moiré potential results in extremely flat moiré valence bands. These two features enable the observation of both the integer and fractional quantum anomalous Hall effects. This device architecture, and the resulting FQAH states observed, are of interest in the development of, among other applications, topological quantum computation.

In one aspect, an electrically tunable material is presented where the material comprises a semiconducting molybdenum ditelluride in the form of a first atomic sheet and a second atomic sheet, wherein first atomic sheet is rotated planarly from the second atomic sheet by about 2.5 to about 4 degrees, to form a rhombohedral stacked homobilayer moiré superlattice that hosts ferromagnetic states that spontaneously break time-reversal symmetry.

The interplay between spontaneous symmetry breaking and topology can result in exotic quantum states of matter. A celebrated example is the quantum anomalous Hall (QAH) state, which exhibits an integer quantum Hall effect at zero magnetic field thanks to its intrinsic ferromagnetism. In the presence of strong electron-electron interactions, exotic fractional-QAH (FQAH) states (or zero-field fractional Chern insulator states) at zero magnetic field can emerge. These states could host fractional excitations, including non-Abelian anyons-crucial building blocks for topological quantum computation. Flat Chern bands are widely considered to be a desirable venue to realize the FQAH state. For this purpose, twisted transition metal dichalcogenide homobilayers in rhombohedral stacking have recently been predicted to be a promising material platform. Here, we report experimental signatures of FQAH states in 2.5-4-degree twisted MoTe₂ bilayer. Magnetic circular dichroism measurements reveal robust ferromagnetic states at fractionally hole filled moiré minibands. Using trion photoluminescence as a sensor, a Landau fan diagram is obtained which shows linear shifts in carrier densities with applied magnetic field. Using the 3.7-degree twisted sample as an example, the states observed correspond to fillings of v=−2/3, −3/5, −4/7. The linear shifts of these features match the Streda formula dispersion of FQAH states with fractionally quantized Hall conductance of

$${σ}_{xy} = - \frac{2}{3} \frac{{e}^{2}}{h} , - \frac{3}{5} \frac{{e}^{2}}{h} , and - \frac{4}{7} \frac{{e}^{2}}{h} ,$$

respectively. Moreover, the v=−1 state exhibits a dispersion corresponding to Chern number −1, consistent with the predicted QAH state. In comparison, several non-ferromagnetic states on the electron doping side do not disperse, i.e., are trivial correlated insulators. The observed topological states can further be electrically driven into topologically trivial states. The measurements provide clear evidence of the long-sought FQAH states, establishing MoTe₂ moiré superlattices as a fascinating platform for exploring fractional excitations.

In an embodiment the electrically tunable material has the first atomic sheet, and the second atomic sheet independently has from one to three atomic layers of semiconducting molybdenum ditelluride.

In an embodiment the electrically tunable material has the first atomic sheet, and the second atomic sheet are rotated planarly from each other by about 3.7 degrees.

In an embodiment the electrically tunable material where the homobilayers have fractional quantum anomalous Hall states.

In an embodiment the electrically tunable material has the fractional quantum anomalous Hall states that are at −2/3, −3/5, and −4/7 filling of the Moiré superlattice.

In an embodiment the electrically tunable material has the homobilayers that are photoluminescent with a linewidth of about 3 meV.

In an embodiment the electrically tunable material has the homobilayers that are luminescent between 1.13 and 1.09 eV.

The fractional quantum anomalous Hall (FQAH) state is the zero magnetic field analog of the fractional quantum Hall state. While both are strongly correlated topological phases of matter, the FQAH state additionally requires spontaneous time-reversal symmetry breaking without Landau level formation. Despite extensive theoretical studies, experimental realization of the FQAH state remains challenging due to the lack of a suitable physical system. A promising approach is to realize the Haldane model on a honeycomb lattice with strong correlations, leading to topological flat bands that share characteristics of Landau levels. Moiré superlattices of two-dimensional materials are emerging platforms for this approach, thanks to their highly tunable flat electronic bands, topology, lattice geometry, and correlation effects. Experimentally, the integer quantum anomalous Hall (QAH) state, a precursor to the FQHE, has been realized in both graphene and twisted transition metal dichalcogenide (TMD) systems. Furthermore, fractional Chern insulator states have been observed in Bernal stacked bilayer graphene/hBN (hexagonal boron nitride) superlattices with a magnetic field near 30T and in magic-angle twisted bilayer graphene with magnetic fields as low as 5 T. All progress points to the 2D moiré superlattice as a powerful platform for engineering flat Chern bands with spontaneous time reversal symmetry breaking at fractional fillings.

In an embodiment the electrically tunable material has the electrically tunable material further comprises of two or more transparent dielectric layers disposed on opposite faces of the rhombohedral stacked homobilayer moiré superlattices.

In an embodiment the electrically tunable material with two or more transparent dielectric layers disposed on opposite faces of the rhombohedral stacked homobilayer moiré superlattices has the transparent dielectric layers independently selected from silicon dioxide, hafnium dioxide, aluminum oxide, zirconium dioxide, titanium dioxide, nitrogen-doped silicon dioxide, high-k dielectric materials, such as barium strontium titanate and hafnium-based high-k dielectrics, graphene oxide, hexagonal boron nitride, molybdenum oxide, tungsten oxide, titanium nitride, germanium oxide, aluminum nitride, gallium oxide, zinc oxide, indium oxide, magnesium oxide, and combinations thereof.

Recent theoretical works have suggested that rhombohedral-stacked TMD moiré bilayer can host topological flat bands with opposite Chern numbers in the two spin/valley sectors. Both integer and fractional QAH states have been predicted in these systems at twist angle near 1.4 degree. Indeed, in near 4-degree twisted MoTe₂ homobilayers, electrically tunable ferromagnetic states that spontaneously break time-reversal symmetry have been observed in a wide range of hole doping phase space, with a Curie temperature as high as 14 K at integer filling v=−1 (one hole per moiré unit cell). Building on this progress, in this work, evidence of FQAH states at zero magnetic field in a fractionally filled moiré superlattice in twisted MoTe₂ bilayer with a twist angle ranging from ~2.5 to 4 degree is provided.

In an embodiment the electrically tunable material has the first atomic sheet, and the second atomic sheet independently has from one to three atomic layers of semiconducting molybdenum ditelluride.

In an embodiment the electrically tunable material has the first atomic sheet, and the second atomic sheet are rotated planarly from each other by about 3.7 degrees.

In an embodiment the electrically tunable material is subject to temperatures of 0.001 to 5 Kelvin. In another embodiment 0.001 to 7.5 Kelvin and in another embodiment 0.001 to 10 Kelvin.

In an embodiment the electrically tunable material is subject to temperatures of 1.6 Kelvin.

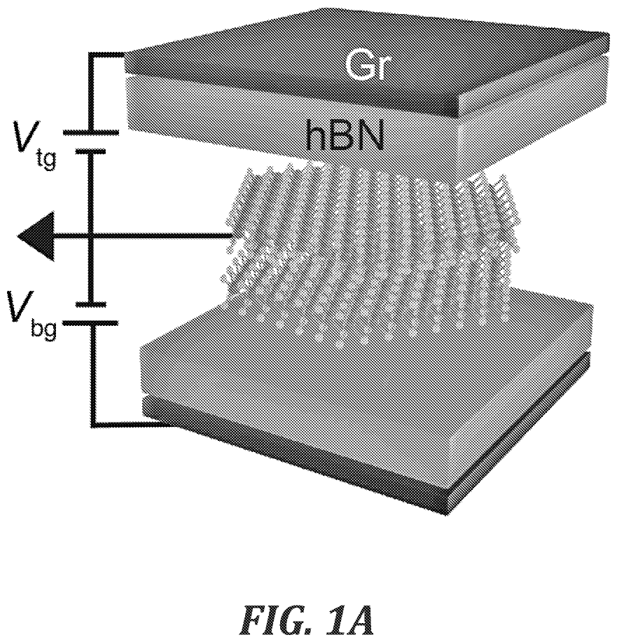

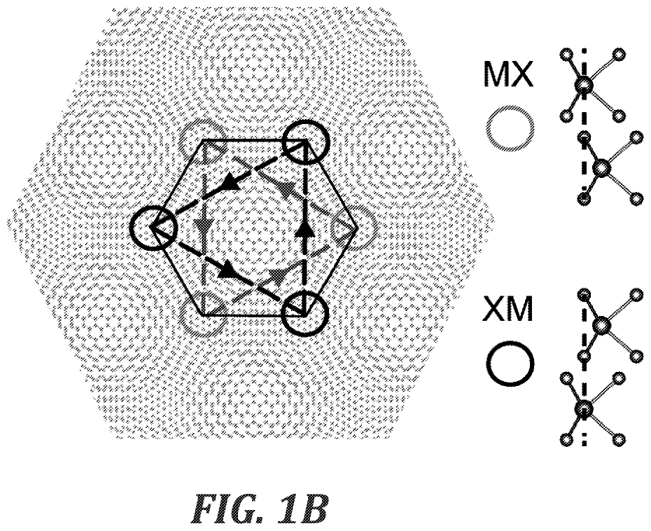

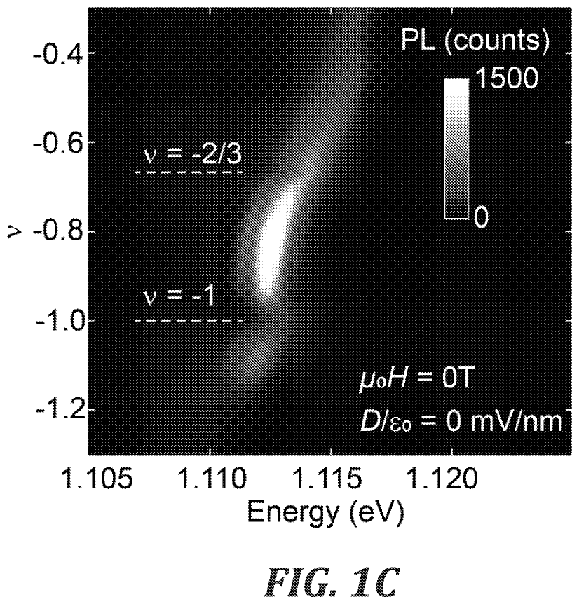

High-quality R-stacked MoTe₂ bilayer samples are fabricated with a twist angle of ~2.5 to 4 degrees. FIG. 1A illustrates the standard dual gate device geometry, which enables independent control of carrier density n and perpendicular electric field D in the sample. The R-stacked bilayer hosts two degenerate energy minima forming a honeycomb lattice (FIG. 1B). The complex hopping between the sublattice sites within the same layer (i.e., next nearest neighbor hopping in the honeycomb lattice) can open a topological band gap when the honeycomb lattice is filled with two holes per cell (v=−2), realizing a Kane-Mele model. For fillings near v=−1 of the honeycomb lattice, ferromagnetism arises due to strong exchange interactions. This lifts the spin-valley flavor degeneracy of the effective Kane-Mele model and realizes a Haldane model with strong Coulomb interactions, i.e., a Haldane-Hubbard model.

Below, a robust ferromagnetism corresponding to correlated insulating states at fractional fillings is established followed by measurement of topological invariants associated with the v=−2/3, −3/5, −4/7 fractionally filled states using an optically detected Landau fan diagram, where evidence of FQAH states is obtained by comparison to the Streda formula dispersion. Lastly, it is demonstrated that these FQAH states can be switched on and off by exploiting electric field control of the lattice geometry, and thus the magnetic ground states and band topology.

In an embodiment the electrically tunable material where the homobilayers have fractional quantum anomalous Hall states.

In an embodiment the electrically tunable material has the fractional quantum anomalous Hall states that are at −2/3, −3/5, and −4/7 filling of the Moiré superlattice.

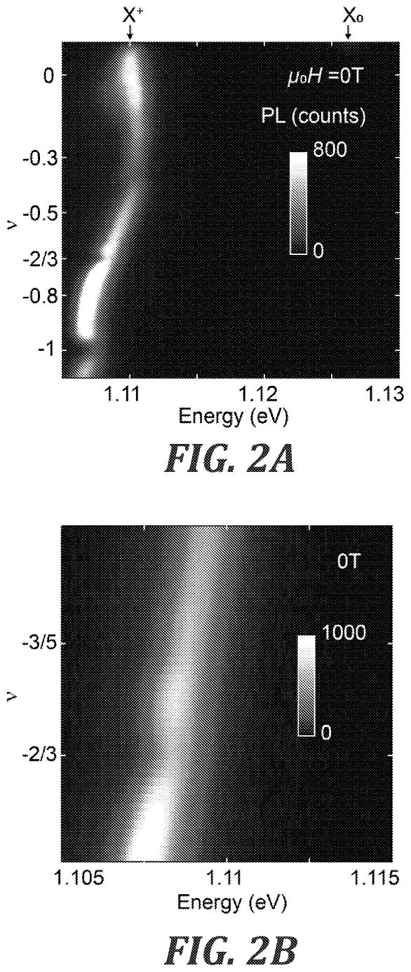

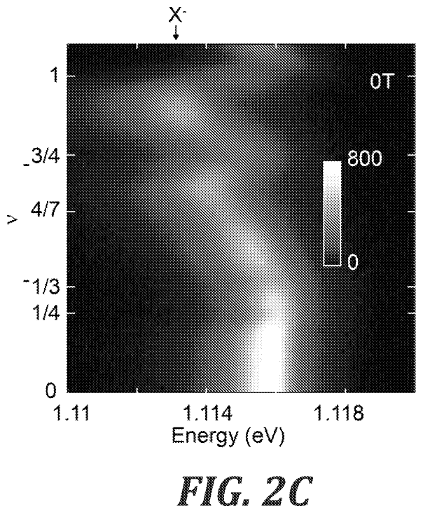

FIG. 1C shows the photoluminescence (PL) intensity plot versus n and photon energy (FIG. 2A-2C). All data are taken at a temperature of ~1.6 K, unless otherwise specified. For doping-dependent measurements, the hole doping side is focused since the electron side is found to be non-ferromagnetic and topologically trivial. At v=−1 and −2/3, PL intensity drops while the peak blue shifts. A weak feature at v=−3/5 can also be observed (FIG. 2A-2C). As reported, this PL resonance arises from the trion (i.e., charged exciton). The observed reduction in PL intensity is a result of reduced trion population, as the formation of correlated insulating states depletes the holes available for trion formation.

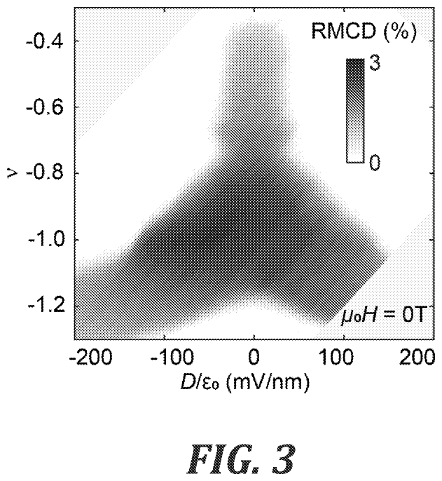

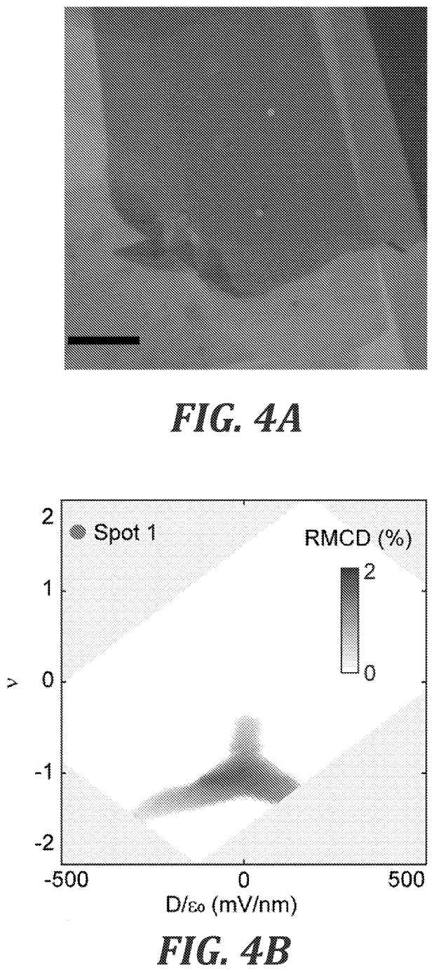

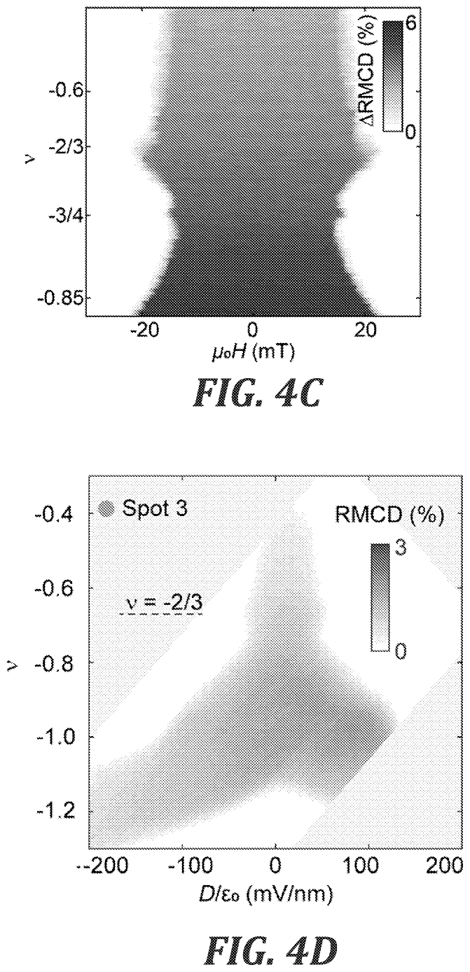

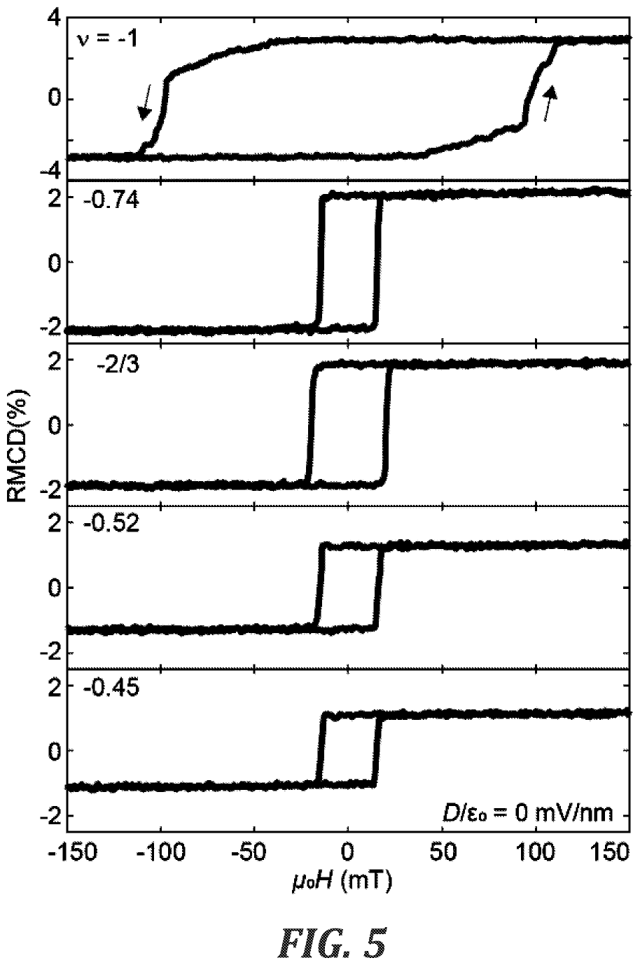

To investigate the magnetic response of the twisted bilayer, reflective magnetic circular dichroism (RMCD) measurements are performed. FIG. 3 is the zero magnetic field RMCD signal intensity plot as a function of v and D (FIG. 4A-4D). The area of non-vanishing RMCD signal highlights the phase space of the ferromagnetic states. Interestingly, the data show that the critical electric field De for suppressing the ferromagnetic state is enhanced at the fractionally filled insulating state v=−2/3. FIG. 5 displays the hysteresis of the RMCD signal versus magnetic field μₒH at selected v. Sharp spin-flip transitions at critical field (i.e., coercive field) H_{C} are observed.

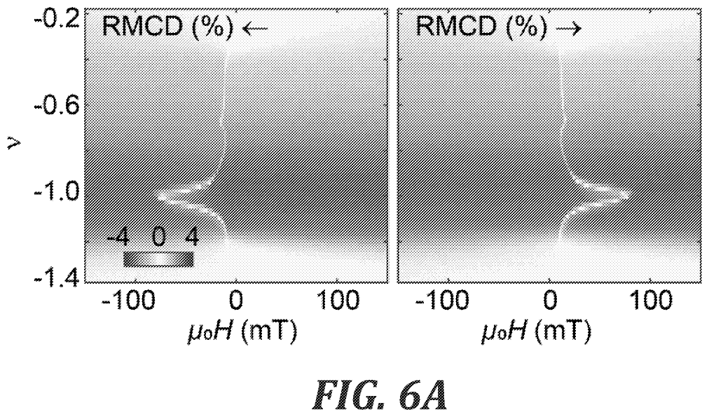

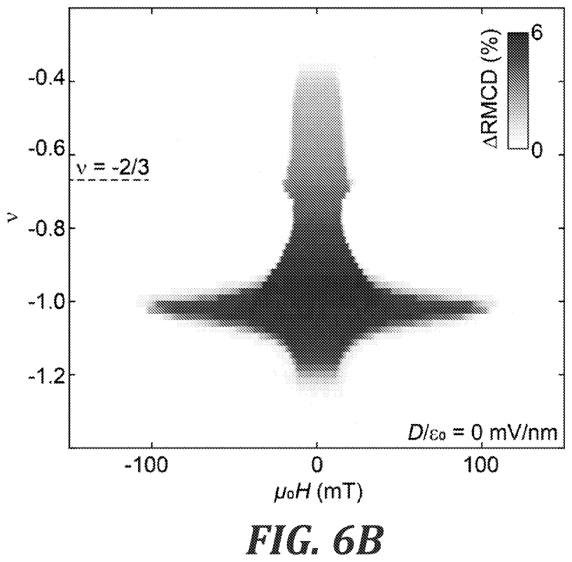

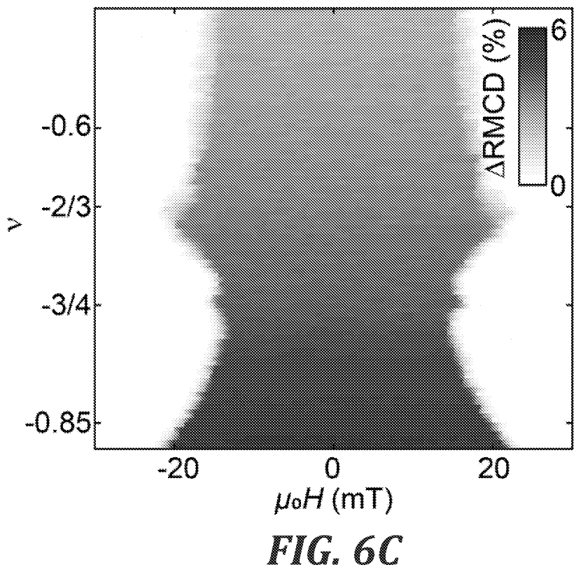

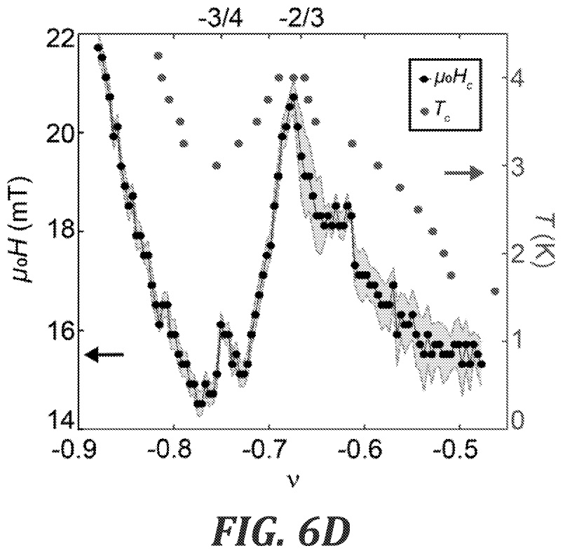

The dependence of hysteresis loops and H_{C} on the correlated insulating states is further highlighted by measurements of the RMCD hysteresis loop as a function of doping. FIG. 6A shows the RMCD intensity plots versus v and μₒH swept down (left) and up (right). The difference between the sweeps is indicated by the intensity plot of the hysteretic component (FIG. 6B). The data clearly show that the coercive field μₒH_{C} is enhanced near the correlated insulating states. As hole doping increases from charge neutrality, μₒH_{C} first grows from ~10 mT to ~20 mT near the v=−2/3 insulating state, then reduces slightly, and subsequently increases drastically up to ~100 mT near the v=−1 insulting state before finally reducing until the ferromagnetic state vanishes.

In an embodiment the electrically tunable material has magnetic field applied between −4 T and 4 T. In an another embodiment the electrically tunable material has magnetic field applied between −1 T and 1 T. In an another embodiment the electrically tunable material has magnetic field applied between −0.5 T and 0.5 T. In an another embodiment the electrically tunable material has magnetic field applied between −0.1 T and 0.1 T. In an embodiment the electrically tunable material has magnetic field applied between −0.01 T and 0.01 T.

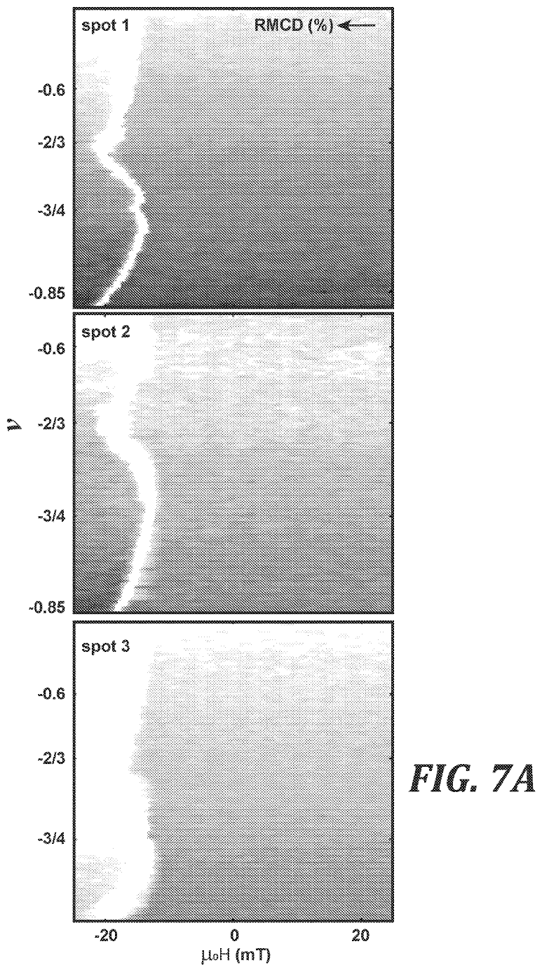

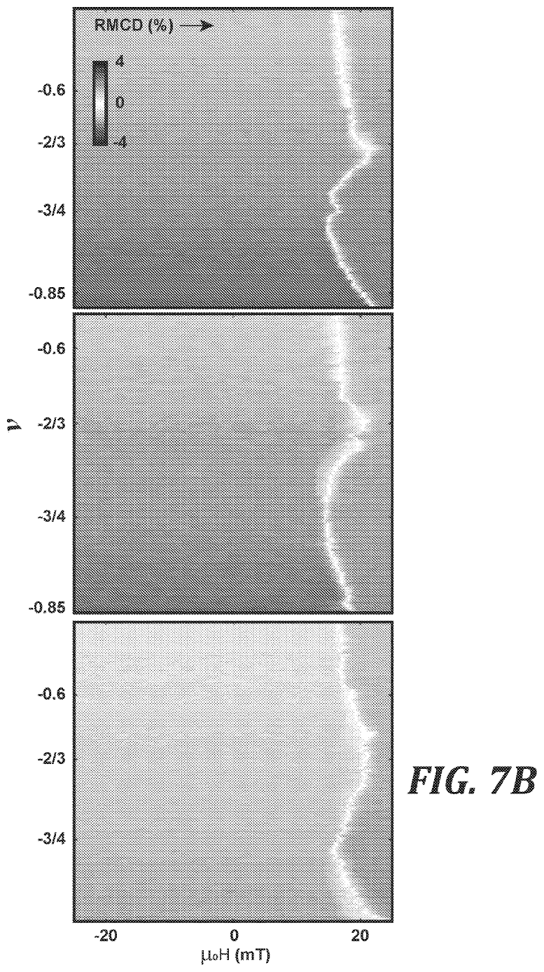

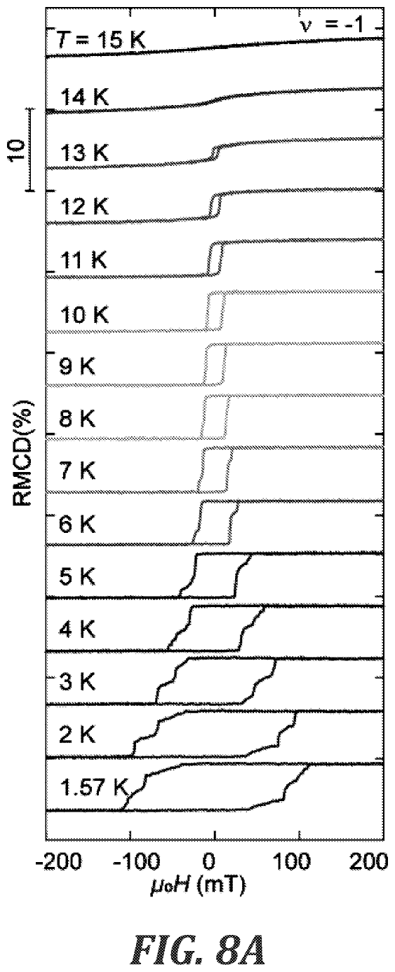

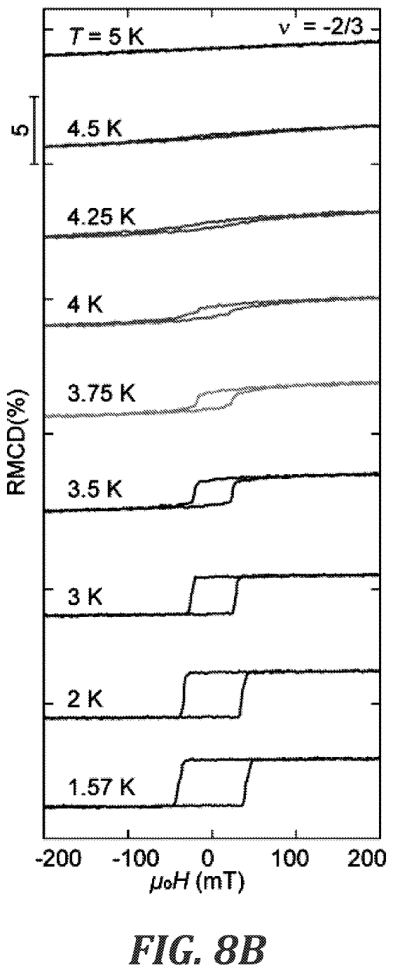

FIG. 6C is a high-resolution plot of the RMCD hysteresis around the fractional filling features. The extracted coercive field H_{C} and Curie temperature T_{C} versus v are shown in FIG. 6D. In addition to the robust v=−2/3 state, a weak and spatially dependent feature exists near v=−3/4 filling in H_{C} (FIG. 7A-7B). As an additional probe of the strength of the ferromagnetic states, temperature dependent RMCD measurements versus filling (FIG. 8A-8B) are performed. The extracted Curie temperature also has a strong dependence on filling factor, peaking at v=−2/3 and −1 where correlated insulating states form, with a T_{C} of ~4.5K and ~14K, respectively. This T_{C} is relatively high considering the large moiré unit cell of period ~5.4 nm and correspondingly low spin density compared to conventional 2D magnets.

Topological invariants associated with gapped incompressible states can be measured via Hall conductivity or with a fan diagram of charge gaps fitted to the Streda formula. In the latter approach, the topological invariant is

$$C = {ϕ}_{o} \frac{\partial n}{\partial B} ,$$

where φₒ is the magnetic flux quantum, n is the carrier density of the gapped state, B is the magnetic field, and C is equal to the Hall conductance (in units of e²/h). The Streda formula approach is particularly suitable when electrical transport measurement is inconvenient. In the fan diagram, if the state is topologically trivial, the carrier density should be independent of the magnetic field. However, the carrier density of gapped topologically nontrivial states should shift linearly versus magnetic field with a quantized slope corresponding to the Chern number.

A trion sensing technique is performed to optically measure the fan diagram. A similar trion sensing technique has been used to image fractional quantum Hall liquids in GaAs/AlGaAs quantum wells. Excitons in TMDs are very sensitive to changes in the local dielectric environment. Thus, they have been used to probe charge gaps of a variety of correlated states, such as generalized Wigner crystal states in TMD moiré superlattices, as well as fractional quantum Hall states in graphene. As shown in FIG. 1C, trion PL intensity drops and its peak energy blue shifts when correlated insulating states form. From this signature, the carrier density is determined corresponding to the v=−1 (n₋₁) and −2/3 (n_{-2/3}) correlated insulating states. The density n₋₁ and n_{-2/3} as a function of magnetic field is measured, probing the topological nature of these ferromagnetic insulating states.

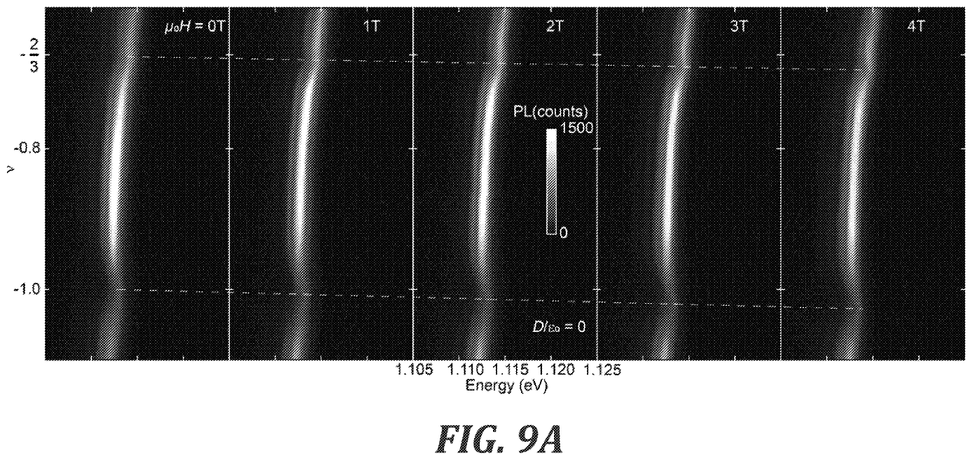

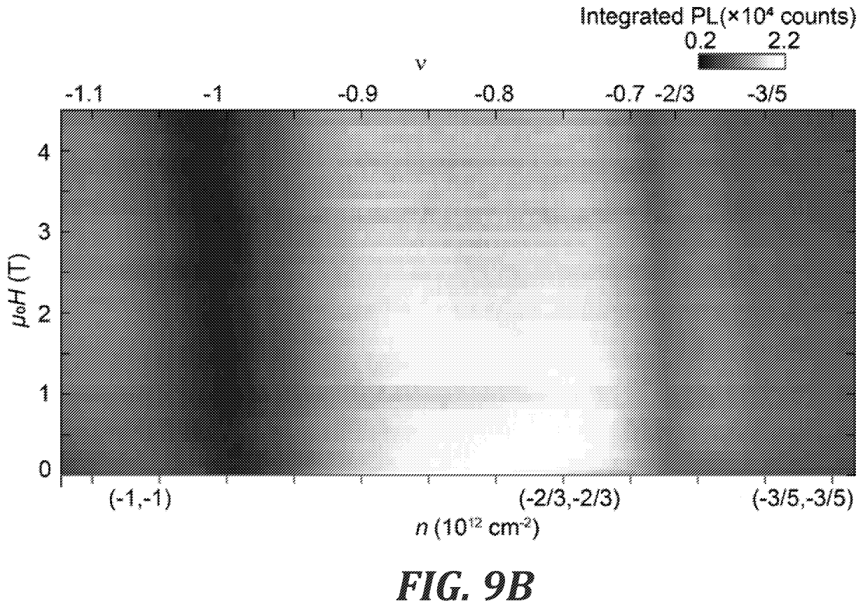

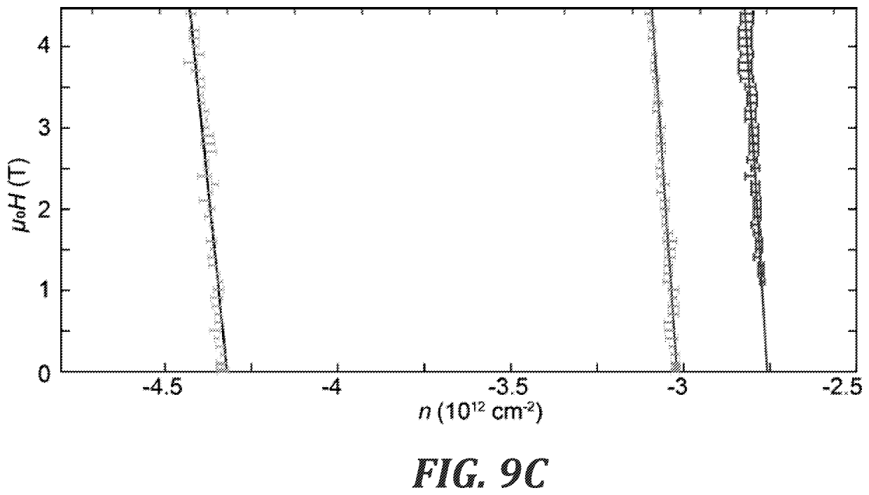

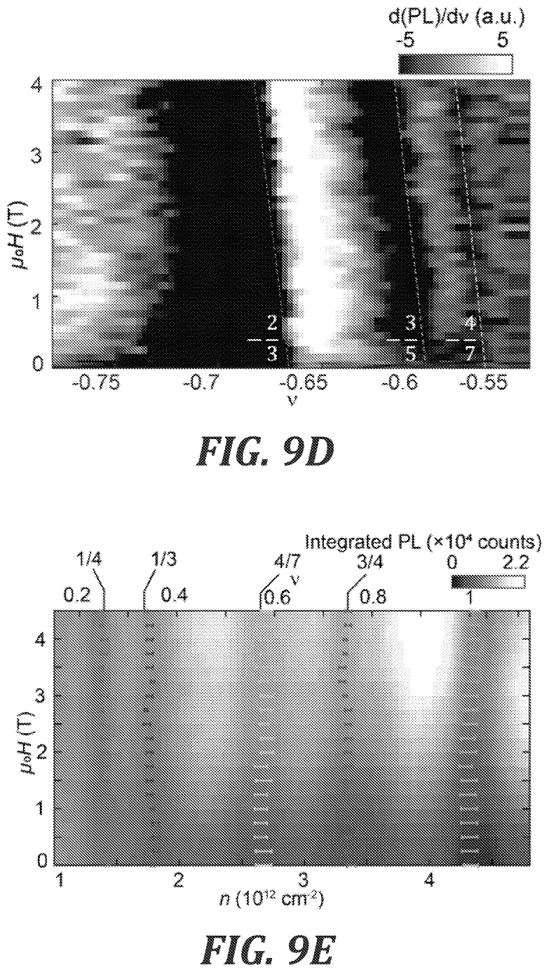

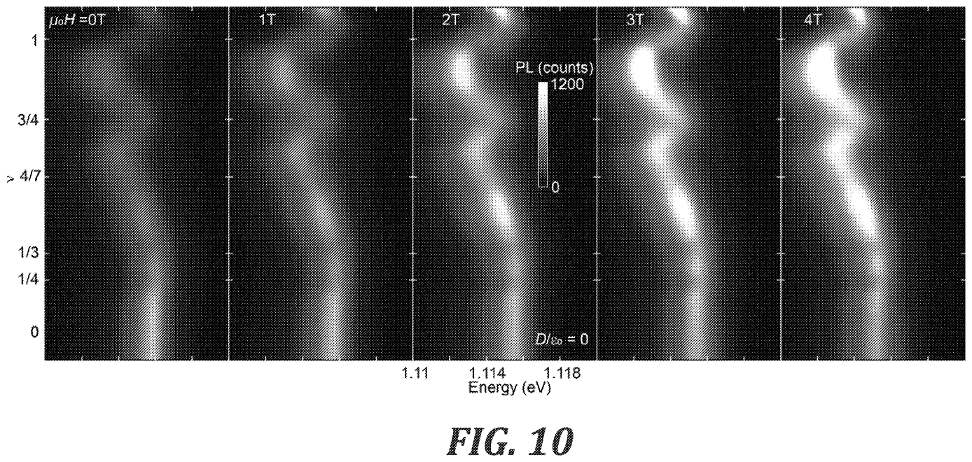

FIG. 9A shows PL intensity plots versus carrier density at selected μₒH, for D=0. The data clearly show that n⁻¹ and n_{-2/3} shift linearly as μₒH increases, with n₋₁ changing with a larger slope than that of n_{-2/3}. The spectrally integrated PL intensity is extracted and plotted as a function of magnetic field and carrier density in FIG. 9B (i.e., the optically detected Landau fan diagram, see EXAMPLES below). It is observed that the v=−1 and −2/3 states show linear dispersions that persist down to zero magnetic field. In addition, there is a weak dispersive feature at v=−3/5. These observations clearly differ from the topologically trivial correlated insulating states at the electron doping side (FIG. 9E and FIG. 10), which are nondispersive. The measured results align with expectations, as these states on the electron doping side are not ferromagnetic—a necessary condition for the formation of both integer and fractional QAH states. FIG. 9C is the Wannier diagram with solid lines indicating dispersion curves determined by the Streda formula, overlaid with the carrier densities extracted from integrated PL in FIG. 9B, which correspond to the integer and fractionally filled states. It is found that Streda dispersions with C=−1 (−4.3 n (10⁻¹² cm⁻²) intercept), −2/3, and C=−3/5 FQAH state at v=−3/5 (−3 and −2.75 n (10⁻¹² cm⁻²) intercepts), match well with the n-μₒH dependence of three correlated ferromagnetic insulating states in FIG. 9B at v=−1, −2/3, and −3/5, respectively. FIG. 9D is the same optical Landau fan diagram shown in FIG. 9B, but with a numerical derivative taken with respect to filling. This additional processing makes the fractional states more apparent and reveals an additional dispersing feature at v=−4/7—the next Jain hierarchy state in the sequence.

In an embodiment the electrically tunable material has optical reflectance.

The observed C=−1 state supports the assignment of the v=−1 ferromagnetic insulating state as a QAH state (or a topological Mott insulator). This observation is consistent with recent predictions from the Haldane Hubbard model with a Chern number of −1. Most importantly, the ferromagnetic insulating states with C=−2/3 and −3/5 at fractional fillings of the flat Chern band are identified as FQAH states, i.e., fractional Chern insulator states which survive to zero magnetic field. These two states are the zero-field analog of the fractional quantum Hall state sequence of odd denominators, hosting fractional charge excitations and Abelian topological orders

Because the sublattice orbitals of the honeycomb lattice are localized in opposite layers of the twisted MoTe₂ bilayer, the application of a perpendicular electric field breaks the layer degeneracy. This enables tuning of the superlattice from a honeycomb to a triangular lattice dominated by kinetic antiferromagnetic exchange interactions. In previous demonstrations a ferromagnetic to antiferromagnetic phase transition concurrent with such a change in lattice geometry. Thus, it is anticipated that this moiré geometry control will fundamentally change the topological properties of the moiré bands and therefore the many-body ground states at integer and fractional fillings.

In an embodiment the electrically tunable homobilayer material has electrically tunable topological phase transitions.

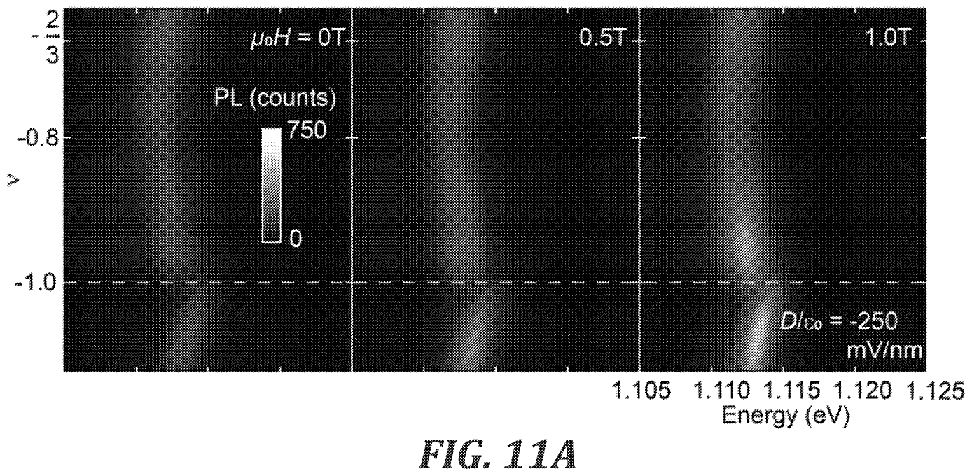

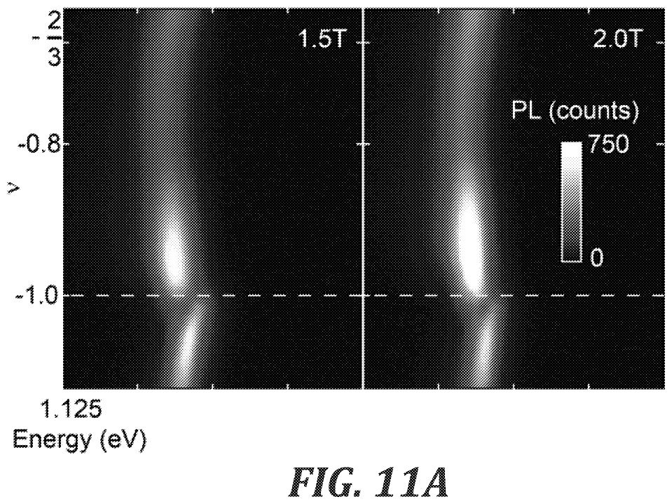

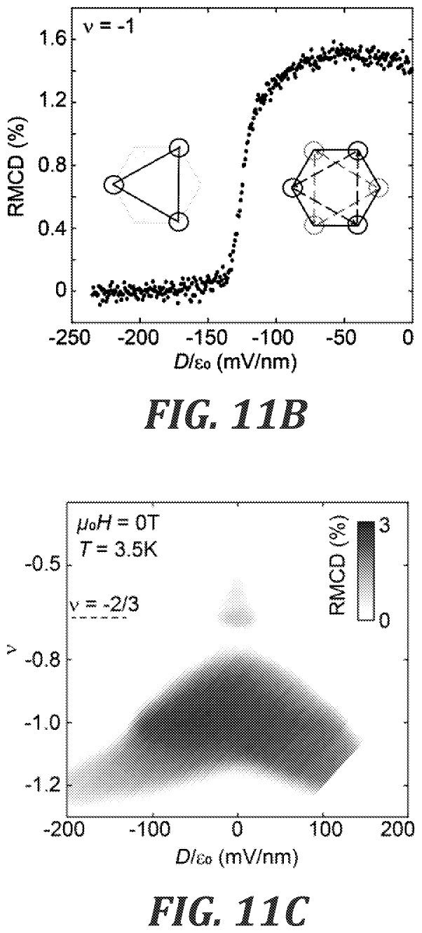

To illustrate this electric field control of topology, the D field is set to −250 m V/nm followed by the measurement of the PL spectra versus n at selected magnetic fields. As shown in FIG. 11A, only the correlated insulating state at v=−1, a Mott state in the triangular lattice, survives at large D. There is no signature of the v=−2/3 state for this large D field. The carrier density corresponding to the v=−1 state becomes independent of magnetic field, demonstrating that the state is now a nondispersive and topologically trivial insulator. FIG. 11B shows the RMCD signal versus D at zero magnetic field. As expected, RMCD signal and thus ferromagnetism vanish at large D, consistent with the observed topologically trivial state.

In an embodiment the electrically tunable material has an electric field applied between-500 mV/nm and 500 mV/nm. In an another embodiment the electrically tunable material has an electric field applied between-250 mV/nm and 250 mV/nm. In an another embodiment the electrically tunable material has an electric field applied between −100 mV/nm and 100 mV/nm.

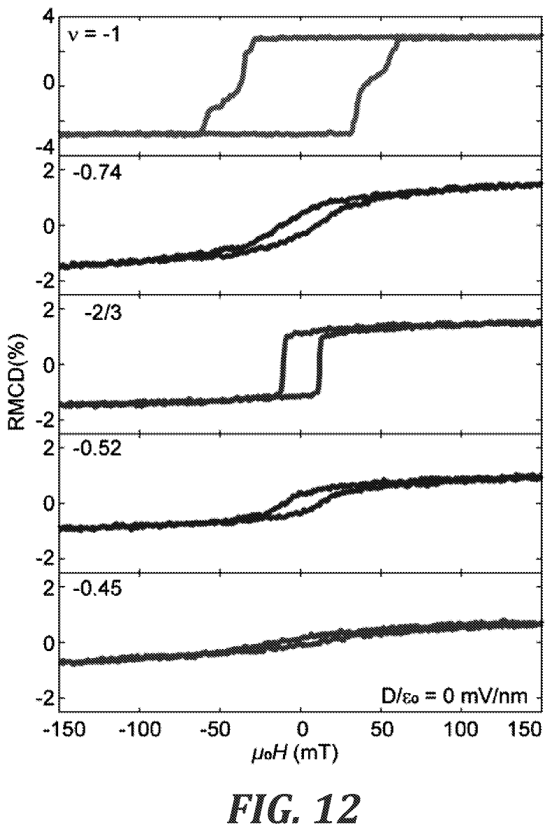

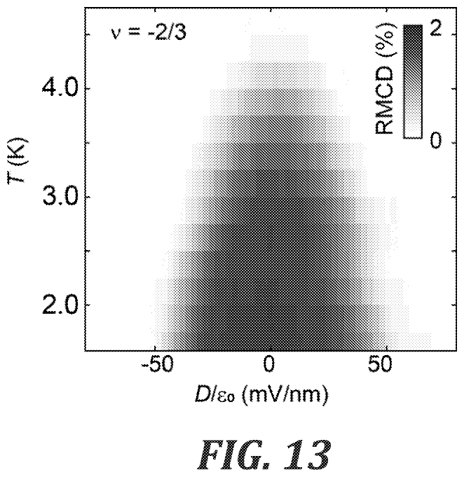

Because the magnetic behavior of the correlated states underpins their topological properties, the magnetic phase diagram of the system is examined as a function of filling, electric field, and temperature. FIG. 11C shows the RMCD signal intensity plot versus v and D at a temperature of 3.5K (FIG. 12 for hysteresis loops at selected fillings). At this temperature, the ferromagnetic states become less robust to the variation of v and D compared to the 1.6K case. It is found that the ferromagnetic phase spaces near v=−1 and v=−2/3 to be disconnected. Though the magnetic states away from v=−2/3 soften significantly compared to their behavior at 1.6K, the v=−2/3 state remains a hard magnet with μₒH_{C}~15 mT. This observation further supports the view that the correlated insulating state at v=−2/3 thermodynamically stabilizes ferromagnetism. FIG. 13 shows the RMCD signal intensity plot of the v=−2/3 state as a function of temperature and D at zero magnetic field, i.e., the magnetic phase diagram of the v=−2/3 state. The D field range of the FM state decreases as temperature increases, eventually vanishing above a T_{C} of about 4.5K. Both temperature and electric field can destroy the ferromagnetic and thus FQAH states, highlighting the high tunability of the twisted MoTe₂ bilayer system.

In an embodiment the electrically tunable material is subject to temperatures of 1.6 Kelvin.

The present disclosure provides for experimental signatures of two FQAH states in twisted MoTe₂ bilayer in R-stacking. The discovered −2/3 and −3/5 FQAH states are expected to host Abelian anyon excitations with fractional statistics. With improved sample quality, it is possible that non-Abelian anyons—a component for realizing topological quantum computation—may be observed in other fractionally filled states. There have been many theoretical developments regarding FQAH states over the past several decades. The presented disclosure provides for an experimental playground to test some of these ideas with unprecedented tunability via electric field, doping, temperature, and magnetic field. An immediate next step is to probe the topological properties using electrical transport measurements. As the spin-valley degree of freedom can be accessed using circularly polarized light, it is also possible to realize optical control of magnetization and thus FQAH (and QAH) states. Furthermore, the data presented indicates for a feasible path to exploit the remarkable properties and tunability of TMD moiré superlattices for quantum engineering of exotic topological orders arising from spontaneous symmetry breaking and strong correlation effects.

### EXAMPLES

The following examples are included for the purpose of illuminating, not limiting, the disclosed embodiments.

### Device Fabrication

Devices were fabricated using the tear-and-stack method. First, hBN, used as the gate dielectric, and graphite, used for the metallic gates, were mechanically exfoliated onto Si/SiO₂ substrates. Homogenous flakes were identified using an optical microscope. hBN thickness was confirmed by atomic force microscope measurements. In an argon filled glovebox with H₂O and O₂ concentrations <0.1 ppm, 2H MoTe₂ (HQ Graphene) was mechanically exfoliated onto Si/SiO₂ substrates with a 285 nm oxide layer precleaned by oxygen plasma. Monolayer flakes were identified via an optical microscope. Standard polymer-based dry transfer techniques were used to fabricate the heterostructure. First, the topmost hBN protection layer, top graphite electrode, hBN top dielectric layer and half of the MoTe₂ monolayer were picked up. Then, the entire stage was rotated by the desired twist angle. After rotation, the second half of the MoTe₂ monolayer was picked up, forming the twisted MoTe₂ interface. The heterostructure was completed by picking up a long strip of graphite to serve as a grounding pin, a bottom hBN dielectric, and the graphite bottom gate. The transfer process was performed at ~100° C. The entire heterostructure was then put down and picked up repeatedly at ~140° C. to mechanically squeeze out trapped gas bubbles between layers, before being melted down onto the substrate at ~170° C. The polymer was dissolved in anhydrous chloroform for 5 minutes in an inert glovebox environment. Standard electron beam lithography was used to electrically connect gold wire bonding pads to the gates and grounding pin of the fully encapsulated device. Liftoff was performed in an inert glovebox environment with anhydrous dichloromethane. Compared to the earlier report of the observation of ferromagnetic states in this system, it is found that a large homogeneous area with reduced moiré disorder is useful for the observations reported in this work (FIG. 4A-4D).

In an embodiment the electrically tunable material comprises further of transparent conductive electrodes disposed on each of the transparent dielectric layers, distal from the Moiré superlattices.

In an embodiment the electrically tunable material where the electrically tunable material has transparent conductive electrodes disposed on each of the transparent dielectric layers, distal from the Moiré superlattices has the transparent conductive electrodes independently selected from gold, platinum, graphene, graphite, indium tin oxide, aluminum zinc oxide, lithium doped nickel oxide, indium doped cadmium oxide, magnesium nitrogen doped chromium trioxide, indium or aluminum doped magnesium zinc oxide, magnesium doped copper chromium oxide, zinc indium tin oxide, zinc oxide, polystyrene sulfonic acid and salts thereof, PEDOT, Nafion, poly(3,4-ethylenedioxythiophene), polyaniline, polyacetylene, polypyrrole, and combinations thereof.

### Determination of Doping Density and Electric Field

The carrier density n and electric field D on the sample are converted from top (bottom) gate voltage V_{tg} (V_{bg}) using a parallel plate capacitor model: n=(V_{tg}C_{tg}+V_{bg}C_{bg})/e−n_{offset} and D/ε₀=(V_{tg}C_{tg}−V_{bg}C_{bg})/2ε₀−D_{offset}, where C_{tg} and C_{bg} are the top and bottom gate capacitance obtained from the device geometry, e is the electron charge, and ε₀ is the vacuum permittivity. The offset carrier density is derived from fitting to the integer and fractional states in PL spectra. The offset electric field is determined from the symmetric axis of the dual gate RMCD map. The obtained doping density from the capacitor model can then be used to calculate twist angle from the assigned filling factors in the optical measurements, which is comparable to the targeted twist angle.

In an embodiment the electrically tunable material has the homobilayers grounded.

In an embodiment the electrically tunable material has a bias is applied to the transparent conductive electrodes.

In an embodiment the electrically tunable material has an applied bias that is between −10 V and 10 V.

### Determination of Chern Number

The optical Landau fan diagram (FIG. 9B) was obtained by integrating PL spectra over a 1 meV spectral range around the peak. To determine the Chern number, first, using the doping density given by hBN capacitance (C_{g}=ε_{hBN}/d, ε_{hBN}=3.0) and assuming the filling to be linear in carrier density, the Landau fan diagram from the PL measurement can be reproduced. The hBN thickness is measured using an atomic force microscope (AFM) with an uncertainty of ~200 μm, which is negligible compared to the 20-40 nm hBN. The largest uncertainty comes from the dielectric constant of hBN (widely accepted as 3-3.3). Second, single-gated reflectance measurements are performed to obtain the capacitance ratio of the top and bottom gates, which matches the thickness ratio obtained by AFM measurements. To quantitatively compare the optical fan diagram with the Streda formula dispersion, the centroid of the integrated PL minimum is extracted as a function of carrier density for each value of the applied magnetic field. The centroid is obtained by calculating the geometric center for the local minimum of the PL intensity. The error bar indicates a 5% deviation of the centroid PL intensity. Using the slope extracted from the Landau fan diagram, the capacitance of the gates can be obtained and compared to the hBN capacitance. This method cross-checks the validity of the hBN capacitance value.

In the foregoing description, specific details are set forth to provide a thorough understanding of representative embodiments of the present disclosure. It will be apparent to one skilled in the art, however, that the embodiments disclosed herein may be practiced without embodying all the specific details. In some instances, well-known process steps have not been described in detail in order not to unnecessarily obscure various aspects of the present disclosure. Further, it will be appreciated that embodiments of the present disclosure may employ any combination of features described herein.

The present disclosure may reference quantities and numbers. Unless specifically stated, such quantities and numbers are not to be considered restrictive, but exemplary of the possible quantities or numbers associated with the present disclosure. Also, in this regard, the present disclosure may use the term “plurality” to reference a quantity or number. In this regard, the term “plurality” is meant to be any number that is more than one, for example, two, three, four, five, etc. The term “about,” “approximately,” etc., means plus or minus 5% of the stated value.

It should be noted that for purposes of this disclosure, terminology such as “upper,” “lower,” “vertical,” “horizontal,” “fore,” “aft,” “inner,” “outer,” “front,” “rear,” etc., should be construed as descriptive and not limiting the scope of the claimed subject matter. Further, the use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this document, the same or similar elements may bear the same references. Furthermore, the presence of reference numbers or letters in the drawings cannot be considered limiting, even when such numbers or letters are indicated in the claims.

The principles, representative embodiments, and modes of operation of the present disclosure have been described in the foregoing description. However, aspects of the present disclosure, which are intended to be protected, are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure as claimed.

While illustrative embodiments have been illustrated and described, it will be appreciated that various changes can be made therein without departing from the spirit and scope of the invention.

1. An electrically tunable material, comprising semiconducting molybdenum ditelluride in the form of a first atomic sheet and a second atomic sheet, wherein first atomic sheet is rotated planarly from the second atomic sheet by about 2.5 to about 4 degrees, to form a rhombohedral stacked homobilayer moiré superlattice that hosts ferromagnetic states that spontaneously break time-reversal symmetry.

2. The electrically tunable material of claim 1, wherein the first atomic sheet and the second atomic sheet independently have from one to three atomic layers of semiconducting molybdenum ditelluride.

3. The electrically tunable material of claim 1, wherein the first atomic sheet and the second atomic sheet are rotated planarly from each other by about 3.7 degrees.

4. The electrically tunable material of claim 1, wherein the homobilayers have electrically tunable topological phase transitions.

5. The electrically tunable material of claim 1, wherein the homobilayers have fractional quantum anomalous Hall states.

6. The electrically tunable material of claim 1, wherein the homobilayers are grounded.

7. The electrically tunable material of claim 1, wherein the electrically tunable material further comprises of two or more transparent dielectric layers disposed on opposite faces of the rhombohedral stacked homobilayer moiré superlattices.

8. The electrically tunable material of claim 7, wherein the transparent dielectric layers are independently selected from silicon dioxide, hafnium dioxide, aluminum oxide, zirconium dioxide, titanium dioxide, nitrogen-doped silicon dioxide, high-k dielectric materials, such as barium strontium titanate and hafnium-based high-k dielectrics, graphene oxide, hexagonal boron nitride, molybdenum oxide, tungsten oxide, titanium nitride, germanium oxide, aluminum nitride, gallium oxide, zinc oxide, indium oxide, magnesium oxide, and combinations thereof.

9. The electrically tunable material of claim 1, wherein the electrically tunable material further comprises of transparent conductive electrodes disposed on each of the transparent dielectric layers, distal from the Moiré superlattices.

10. The electrically tunable material of claim 9, wherein the transparent conductive electrodes are independently selected from gold, platinum, graphene, graphite, indium tin oxide, aluminum zinc oxide, lithium doped nickel oxide, indium doped cadmium oxide, magnesium nitrogen doped chromium trioxide, indium or aluminum doped magnesium zinc oxide, magnesium doped copper chromium oxide, zinc indium tin oxide, zinc oxide, polystyrene sulfonic acid and salts thereof, PEDOT, Nafion, poly(3,4-ethylenedioxythiophene), polyaniline, polyacetylene, polypyrrole, and combinations thereof.

11. The electrically tunable material of claim 10, wherein the bias is applied to the transparent conductive electrodes.

12. The electrically tunable material of claim 1, wherein the bias is between-10 V and 10 V.

13. The electrically tunable material of claim 1, wherein the fractional quantum anomalous Hall states are at −2/3, −3/5, and −4/7 filling of the moiré superlattice.

14. The electrically tunable material of claim 1, wherein the homobilayers exhibit a photoluminescence, wherein the photoluminescence has a linewidth of about 3 meV.

15. The electrically tunable material of any of claim 14, wherein the homobilayers, wherein the photoluminescence is between 1.13 and 1.09 eV.

16. The electrically tunable material of claim 1, wherein an electric field is applied to the electrically tunable material, wherein the electric field is from −500 mV/nm to −500 mV/nm.

17. The electrically tunable material of claim 1, wherein a magnetic field is applied to the electrically tunable material, wherein the magnetic field is from −4 T to 4 T.

18. The electrically tunable material of claim 1, wherein the electrically tunable material has an optical reflectance.

19. The electrically tunable material of claim 1, wherein the electrically tunable material is subject temperatures of 0.001 to 5 Kelvin.

20. The electrically tunable material of claim 19, wherein the electrically tunable material is subject to a temperature of 1.6 Kelvin.
